(19) United States
(12) Patent Application Publication
(10) Pub. No.: US 2012/0313487 A1
(43) Pub. Date: Dec. 13, 2012

(54) ULTRASONIC SENSOR

(75) Inventors: Boum Seock KIM, Gyeonggi-do (KR); Sung Kwon Wi, Seoul (KR); Eun Tae Park, Gyeonggi-do (KR)

(73) Assignee: SAMSUNG ELECTRO-MECHANICS CO., LTD., Suwon (KR)

(21) Appl. No.: 13/464,491

(22) Filed: May 4, 2012

(30) Foreign Application Priority Data
Jun. 9, 2011 (KR) 10-2011-0055710

(51) Int. Cl. H01L 41/08

(52) U.S. Cl. 310/346

(57) ABSTRACT

Disclosed herein is an ultrasonic sensor, including: a conductive case having a groove disposed at a bottom surface thereof; a piezoelectric element inserted into the groove and fixed to the groove by a conductive adhesive; a temperature compensation capacitor disposed on a top of the piezoelectric element, electrically connected to the piezoelectric element, and fixed to the case by a non-conductive adhesive; a first lead wire led-in from an outside of the case and electrically connected to one surface of the temperature compensation capacitor and the case; and a second lead wire lead-in from the outside of the case and electrically connected to the other surface of the temperature compensation capacitor, whereby the piezoelectric element which is easily damaged can be protected by the temperature compensation capacitor, without using the separate substrate for fixing the temperature compensation capacitor.

### CROSS REFERENCE(S) TO RELATED APPLICATIONS

This application claims the benefit under 35 U.S.C. Section 119 of Korean Patent Application Serial No. 10-2011-0055710, entitled “Ultrasonic Sensor” filed on Jun. 9, 2011, which is hereby incorporated by reference in its entirety into this application.

### BACKGROUND OF THE INVENTION

1. Technical Field

The present invention relates to a sensor, and more particularly, to an ultrasonic sensor capable of measuring a distance to objects to be measured by generating an ultrasonic wave using a piezoelectric element and using time consumed to return the generated ultrasonic wave reflected from the objects to be measured.

2. Description of the Related Art

As an ultrasonic sensor, two types such as a piezoelectricity type and a magnetostriction type have been generally used. The piezoelectricity type means a type using a phenomenon of inducing voltage when pressure is applied to objects such as crystal, PZT (piezoelectric material), piezoelectric polymer, or the like, and to the contrary, inducing vibrations when voltage is applied thereto. On the other hand, the magnetostriction type means a type using a Joule effect (a phenomenon generating vibrations when applying a magnetic field) and a Villari effect (a phenomenon generating a magnetic field when applying stress) that are shown on an alloy of iron, nickel, and cobalt, or the like.

An ultrasonic element may be referred to as an ultrasonic sensor and an ultrasonic generator. The piezoelectricity type senses the ultrasonic wave using voltage generated when ultrasonic vibrations are applied to the piezoelectric element and generates the ultrasonic wave by vibrations generated when voltage is applied to the piezoelectric element. The magnetostriction type generates the ultrasonic wave by the Joule effect and senses the ultrasonic wave by the Villari effect.

Currently, the ultrasonic sensor generally used is operated by the piezoelectricity type using the piezoelectric element and has a structure in which the piezoelectric element is seated in a case and the ultrasonic wave generated from the piezoelectric element is discharged to the outside through the case.

Further, since the sensitivity of the piezoelectric element is changed according external temperature, a temperature compensation capacitor for compensating for the change in sensitivity is disposed in the case and the substrate for fixing the temperature compensation capacitor is mounted therein. The substrate serves as a terminal of a wire connecting the piezoelectric elements with the temperature compensation capacitor, or the like.

In addition, a sound absorbing material for absorbing vibration energy of the piezoelectric element to shorten reverberation time and protect internal parts is disposed in the case. The sound absorbing material is generally used as a nonwoven fabric.

As described above, the ultrasonic sensor has various parts disposed therein, wherein each part is electrically connected to the wire through the substrate.

However, since the substrate and the temperature compensation capacitor fixed to the substrate are disposed at a portion that is difficult to handle the equipment, it is difficult to mass-produce and automatically produce the ultrasonic sensor.

In addition, the sound absorbing material for shortening the reverberation time reduces vibrations of the piezoelectric element and thus, the vibration force of the piezoelectric element is weak. Therefore, since the intensity of the ultrasonic wave generated from the piezoelectric element is weak, the sensed distance of the ultrasonic sensor may be reduced.

### SUMMARY OF THE INVENTION

An object of the present invention is to provide an ultrasonic sensor capable of improving a vibration force of a piezoelectric element while increasing a sensed distance without using a substrate for fixing a temperature compensation capacitor.

According to an exemplary embodiment of the present invention, there is provided an ultrasonic sensor, including: a conductive case having a groove disposed at a bottom surface thereof; a piezoelectric element inserted into the groove and fixed to the groove by a conductive adhesive; a temperature compensation capacitor disposed on a top of the piezoelectric element, electrically connected to the piezoelectric element, and fixed to the case by a non-conductive adhesive; a first lead wire lead-in from an outside of the case and electrically connected to one surface of the temperature compensation capacitor and the case; and a second lead wire lead-in from the outside of the case and electrically connected to the other surface of the temperature compensation capacitor.

The piezoelectric element and the temperature compensation capacitor may be electrically connected to each other by conductive adhesive.

The conductive adhesive electrically connecting the piezoelectric element to the temperature compensation capacitor may be connected to an edge of the piezoelectric element.

The piezoelectric element and the temperature compensation capacitor may be electrically connected to each other by a wire.

The wire may be connected to the edge of the piezoelectric element.

The ultrasonic sensor may further include a sound absorbing material disposed on the top of the temperature compensation capacitor.

The ultrasonic sensor may further include a molding part filled in the case.

### BRIEF DESCRIPTION OF THE DRAWINGS

FIG. 1 is a perspective view of an ultrasonic sensor according to an exemplary embodiment of the present invention.

FIG. 2 is a cross-sectional view taken along the line A-A′ shown in FIG. 1.

FIG. 3 is a partially enlarged view of portion B shown in FIG. 1.

### DESCRIPTION OF THE PREFERRED EMBODIMENTS

Hereinafter, exemplary embodiments of the present invention will be described with reference to the accompanying drawings. However, the exemplary embodiments are described by way of examples only and the present invention is not limited thereto.

In describing the present invention, when a detailed description of well-known technology relating to the present invention may unnecessarily make unclear the spirit of the present invention, a detailed description thereof will be omitted. Further, the following terminologies are defined in consideration of the functions in the present invention and may be construed in different ways by the intention of users and operators. Therefore, the definitions thereof should be construed based on the contents throughout the specification.

As a result, the spirit of the present invention is determined by the claims and the following exemplary embodiments may be provided to efficiently describe the spirit of the present invention to those skilled in the art.

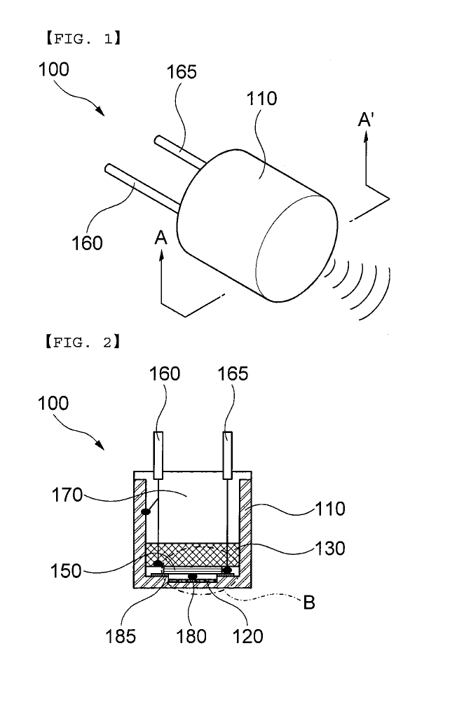

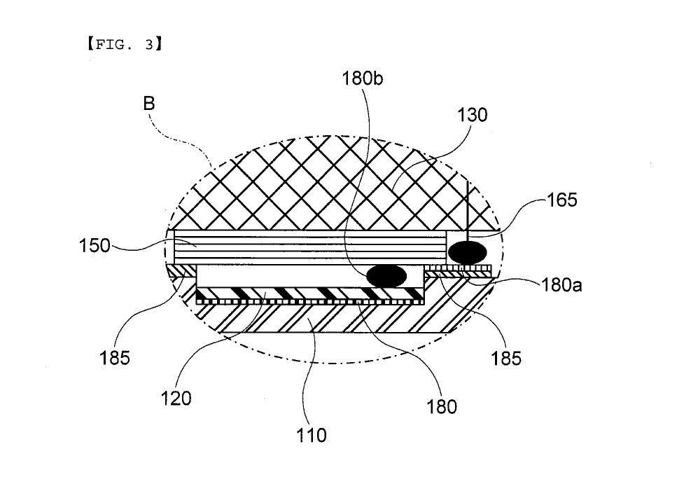

FIG. 1 is a perspective view of an ultrasonic sensor according to an exemplary embodiment of the present invention, FIG. 2 is a cross-sectional view taken along the line A-A′ shown in FIG. 1, and FIG. 3 is a partially enlarged view of portion B shown in FIG. 1. Referring to FIGS. 1 to 3, an ultrasonic sensor 100 according to an exemplary embodiment of the present invention includes a case 110, a piezoelectric element 120, a temperature compensation capacitor 150, a first lead wire 160, and a second lead wire 165.

The case 110 is made of a conductive material and has a space in which parts may be accommodated. In addition, a bottom surface of the case 110 is provided with a groove into which the piezoelectric element 120 generating ultrasonic waves is inserted.

The piezoelectric element 120 is a part that is displaced when current is applied thereto. Therefore, the piezoelectric element 120 is expanded or contracted according to polarity of the applied current. Therefore, when the polarity of the current applied to the piezoelectric element 120 is repeatedly changed, the piezoelectric element 120 generates vibrations by repeating the expansion and contraction. The ultrasonic wave is generated from the piezoelectric element 120 by the above principle.

Meanwhile, the piezoelectric element 120 is attached to the bottom surface of the case 110 through a conductive adhesive 180 and the bottom surfaces of the case 110 and the piezoelectric element 120 are electrically connected to each other.

Meanwhile, the piezoelectric element 120 has property in which the capacitance value thereof is changed according to temperature. For this reason, the reverberation vibration of the piezoelectric element 120 is increased at low temperature, such that the system is mal-functional and the sensitivity of the piezoelectric element 120 is degraded at high temperature, such that the sensed distance thereof is reduced.

In order to prevent the above phenomenon, the change value in capacitance of the piezoelectric element 120 is compensated by the temperature compensation capacitor 150. The temperature compensation capacitor 150 is disposed on the top of the piezoelectric element 120 and the top surface of the piezoelectric element 120 is electrically connected to the bottom surface of the temperature compensation capacitor 150.

Referring to FIG. 3 in more detail, the piezoelectric element 120 is seated in the groove formed on the bottom surface of the case 110 and the temperature compensation capacitor 150 is attached to the case 110 while covering the groove in a lid form. In this configuration, the temperature compensation capacitor 150 is bonded to the case 110 through a non-conductive adhesive 185 in an insulated state.

Therefore, the ultrasonic sensor 100 according to the exemplary embodiment of the present invention may safely protect the piezoelectric element 120, which is easily damaged, by the temperature compensation capacitor 150, without using a separate substrate for fixing the temperature compensation capacitor 150.

Meanwhile, the first lead wire 160 is lead-in from the outside of the case 110 and is electrically connected to the top surface of the temperature compensation capacitor 150 and the case 110.

Further, a conductive adhesive 180a is disposed between the temperature compensation capacitance 150 and the non-conductive adhesive 185, and the conductive adhesive 180a is connected to the second lead wire 165 that is lead-in from the outside. That is, the temperature compensation capacitor 150 of which the bottom surface is attached to the bottom surface of the case 110 is insulated from the case 110 and is electrically connected to the second lead wire 165.

In addition, the bottom surface of the temperature compensation capacitor 150 is electrically connected to the top surface of the piezoelectric element 120. In this configuration, the piezoelectric element 120 and the temperature compensation capacitor 150 may be electrically connected to each other by the conductive adhesive 180b.

Further, the conductive adhesive 180b electrically connecting the piezoelectric element 120 with the temperature compensation capacitor 150 may be connected to the edge of the piezoelectric element 120. Since the strongest vibration force is generated at the central portion of the piezoelectric element 120, the vibration force may be affected when the conductive adhesive 180b is disposed thereat. Therefore, it is preferable that the conductive adhesive 180b is disposed at an edge of the piezoelectric element 120 rather than at the central portion thereof.

Further, the piezoelectric element 120 and the temperature compensation capacitor 150 may be electrically connected to each other by the wire (not shown). Similarly, it is preferable that the wire (not shown) is also connected to the edge of the piezoelectric element 120 so as not to affect the vibration force of the piezoelectric element 120.

Further, the ultrasonic sensor 100 according to the exemplary embodiment of the present invention may further include the sound absorbing material 130 disposed on the top of the temperature compensation capacitor 150. The sound absorbing material 130 reduces the reverberation generated after the ultrasonic wave is generated from the piezoelectric element 120.

The piezoelectric element 120 serves to generate the ultrasonic wave and sense the ultrasonic wave reflected and returned from the object to be measured, which may sense the reflected ultrasonic wave only in the case in which the reverberation generated after the ultrasonic wave is generated is completely removed.

Therefore, when the reverberation of the piezoelectric element 120 lasts long, it takes much time to sense the ultrasonic wave and thus, it takes much time for the ultrasonic sensor 100 to sense the distance.

As described above, the sound absorbing material 130 serves to shorten the sensed time of the ultrasonic sensor 100 by reducing the reverberation generated from the piezoelectric element 120.

In the related art, the sound absorbing material 130 is closely disposed to the piezoelectric element 120, such that the vibration force of the piezoelectric element 120 is reduced. However, in the exemplary embodiment of the present invention, the sound absorbing material 130 completely separates from the piezoelectric element 120 to remarkably improve the vibration force of the piezoelectric element 120, such that the sensed distance of the ultrasonic sensor 100 is increased.

In addition, the ultrasonic sensor 100 according to the exemplary embodiment of the present invention may further include a molding part 170. The molding part 170, which is manufactured by injecting and hardening a molding solution into the case 110, serves to fix and seal the parts disposed in the case 110.

As set forth above, the ultrasonic sensor according to the exemplary embodiment of the present invention can protect the piezoelectric element, which is easily destroyed, using the temperature compensation capacitor, without using a separate substrate for fixing the temperature compensation capacitor.

In addition, the exemplary embodiment of the present invention can separate the piezoelectric element from the sound absorbing material to remarkably improve the vibration force of the piezoelectric element, thereby increasing the sensed distance of the ultrasonic sensor.

Although the exemplary embodiments of the present invention have been disclosed for illustrative purposes, those skilled in the art will appreciate that various modifications, additions and substitutions are possible, without departing from the scope and spirit of the invention as disclosed in the accompanying claims.

Accordingly, the scope of the present invention is not construed as being limited to the described embodiments but is defined by the appended claims as well as equivalents thereto.

1. An ultrasonic sensor, comprising:
a conductive case having a groove disposed at a bottom surface thereof;
a piezoelectric element inserted into the groove and fixed to the groove by a conductive adhesive;
a temperature compensation capacitor disposed on a top of the piezoelectric element, electrically connected to the piezoelectric element, and fixed to the case by a non-conductive adhesive;
a first lead wire lead-in from an outside of the case and electrically connected to one surface of the temperature compensation capacitor and the case; and
a second lead wire lead-in from the outside of the case and electrically connected to the other surface of the temperature compensation capacitor.

2. The ultrasonic sensor according to claim 1, wherein the piezoelectric element and the temperature compensation capacitor are electrically connected to each other by the conductive adhesive.

3. The ultrasonic sensor according to claim 2, wherein the conductive adhesive electrically connecting the piezoelectric element to the temperature compensation capacitor is connected to an edge of the piezoelectric element.

4. The ultrasonic sensor according to claim 1, wherein the piezoelectric element and the temperature compensation capacitor are electrically connected to each other by a wire.

5. The ultrasonic sensor according to claim 4, wherein the wire is connected to the edge of the piezoelectric element.

6. The ultrasonic sensor according to claim 1, further comprising a sound absorbing material disposed on the top of the temperature compensation capacitor.

7. The ultrasonic sensor according to claim 1, further comprising a molding part filled in the case.

8. The ultrasonic sensor according to claim 2, further comprising a sound absorbing material disposed on the top of the temperature compensation capacitor.

9. The ultrasonic sensor according to claim 3, further comprising a sound absorbing material disposed on the top of the temperature compensation capacitor.

10. The ultrasonic sensor according to claim 4, further comprising a sound absorbing material disposed on the top of the temperature compensation capacitor.

11. The ultrasonic sensor according to claim 5, further comprising a sound absorbing material disposed on the top of the temperature compensation capacitor.

12. The ultrasonic sensor according to claim 2, further comprising a molding part filled in the case.

13. The ultrasonic sensor according to claim 3, further comprising a molding part filled in the case.

14. The ultrasonic sensor according to claim 4, further comprising a molding part filled in the case.

15. The ultrasonic sensor according to claim 5, further comprising a molding part filled in the case.
